(19) United States
(12) Patent Application Publication
(10) Pub. No.: US 2024/0344783 A1
(43) Pub. Date: Oct. 17, 2024

(54) COOLING STRUCTURE HAVING METAL PLATING LAYER

(71) Applicant: AMULAIRE THERMAL TECHNOLOGY, INC., New Taipei City (TW)

(72) Inventors: CHING-MING YANG, New Taipei City (TW); KUN-LIN CHIH, New Taipei City (TW); YI-SHENG LU, New Taipei City (TW); TZE-YANG YEH, New Taipei City (TW)

(21) Appl. No.: 18/299,719

(22) Filed: Apr. 13, 2023

(51) Int. Cl. F28F 13/18

(52) U.S. Cl. CPC F28F 13/18; C23C 28/021; F28F 3/022

(57) ABSTRACT

A cooling structure having a metal plating layer is provided with a substrate, a first metal plating layer and a second metal plating layer that are made of materials different from each other and formed on the substrate by different processes. The first metal plating layer is formed on the substrate by a wetting process. The second metal plating layer having a thickness ranging from 0.1 μm to 5 μm is formed on the first metal plating layer by a sputtering process. The second metal plating layer includes at least three blocks arranged at intervals, and at least two adjacent ones of the at least three blocks have a distance therebetween that is not equal to a distance between another two adjacent ones of the at least three blocks.

### FIELD OF THE DISCLOSURE

The present disclosure relates to a cooling structure, and more particularly to a cooling structure having a metal plating layer.

### BACKGROUND OF THE DISCLOSURE

Some heat sinks are coated with sintered coatings on the surface, and the heat sinks are connected with power chips through the sintered coatings. However, shrinkage of the coatings after sintering and stress impact caused by changes in heat of the power chip during operation are unfavorable to the heat sinks.

### SUMMARY OF THE DISCLOSURE

The technical problem to be solved by the present disclosure is to provide a cooling structure having a metal plating layer.

Embodiments of the present disclosure provide a cooling structure having a metal plating layer, including: a substrate, and a first metal plating layer and a second metal plating layer that are made of materials different from each other and formed on the substrate by different processes. The first metal plating layer is formed on the substrate by a wetting process, the second metal plating layer having a thickness ranging from 0.1 μm to 5 μm is formed on the first metal plating layer by a sputtering process, the second metal plating layer includes at least three blocks arranged at intervals, and at least two adjacent ones of the at least three blocks have a distance therebetween that is not equal to a distance between another two adjacent ones of the at least three blocks.

In one of the possible or preferred embodiments, the substrate is at least one of a copper/copper alloy layer and an aluminum/aluminum alloy layer.

In one of the possible or preferred embodiments, the first metal plating layer is at least one of a nickel/nickel alloy layer and a nickel-phosphorus alloy layer.

In one of the possible or preferred embodiments, the second metal plating layer is a silver/silver alloy layer.

In one of the possible or preferred embodiments, a plurality of blocks of the second metal plating layer are arranged symmetrically with respect to a centerline of the substrate, and an arrangement distance between two blocks closest to the centerline of the substrate is greater than an arrangement distance between other blocks.

In one of the possible or preferred embodiments, based on the arrangement distance between the two blocks closest to the centerline of the substrate, the arrangement distance between other blocks is gradually reduced by ½\hat{ }N times of the arrangement distance between the two blocks closest to the centerline of the substrate in a direction away from the centerline, where N starts from 1 and increments by 1.

In one of the possible or preferred embodiments, under a condition that the plurality of blocks are rectangular and have a same size, the arrangement distance between two blocks closest to the centerline of the substrate is twice a width of each block along the arrangement direction.

In one of the possible or preferred embodiments, a plurality of fins are integrally formed on a surface of the substrate, and the plurality of fins are pin fins.

In one of the possible or preferred embodiments, the substrate has a water inlet and a water outlet that are in fluid communication.

In one of the possible or preferred embodiments, multiple ones of the second metal plating layers are formed in parallel with each other on the first metal plating layer on the substrate.

Embodiments of the present disclosure further provide a cooling structure having a metal plating layer, including: a substrate, and a first metal plating layer and a second metal plating layer that are made of materials different from each other and formed on the substrate by different processes. The first metal plating layer is formed on the substrate by a wetting process, the second metal plating layer having a thickness ranging from 0.1 μm to 5 μm is formed on the first metal plating layer by a sputtering process, the first metal plating layer is formed on the substrate not covered by the second metal plating layer, the second metal plating layer includes at least three blocks arranged at intervals, and at least two adjacent ones of the at least three blocks have a distance therebetween that is not equal to a distance between another two adjacent ones of the at least three blocks.

Embodiments of the present disclosure further provide a cooling structure having a metal plating layer, including: a substrate and at least a metal plating layer formed on the substrate. The metal plating layer having a thickness ranging from 0.1 μm to 5 μm is formed on the substrate by a sputtering process, the metal plating layer includes at least three blocks arranged at intervals, and at least two adjacent ones of the at least three blocks have a distance therebetween that is not equal to a distance between another two adjacent ones of the at least three blocks.

These and other aspects of the present disclosure will become apparent from the following description of the embodiment taken in conjunction with the following drawings and their captions, although variations and modifications therein may be affected without departing from the spirit and scope of the novel concepts of the disclosure.

### BRIEF DESCRIPTION OF THE DRAWINGS

The described embodiments may be better understood by reference to the following description and the accompanying drawings, in which:

FIG. 1 is a schematic top view of the structure of a first embodiment according to the present disclosure;

FIG. 2 is a schematic side view of the structure of the first embodiment according to the present disclosure;

FIG. 3 is a schematic top view of the structure of a second embodiment according to the present disclosure;

FIG. 4 is a schematic side view of the structure of the second embodiment according to the present disclosure;

FIG. 5 is a schematic top view of the structure of a third embodiment according to the present disclosure;

FIG. 6 is a schematic side view of the structure of a fourth embodiment according to the present disclosure; and

FIG. 7 is a schematic side view of a fifth embodiment according to the present disclosure.

### DETAILED DESCRIPTION OF THE EXEMPLARY EMBODIMENTS

The present disclosure is more particularly described in the following examples that are intended as illustrative only since numerous modifications and variations therein will be apparent to those skilled in the art. Like numbers in the drawings indicate like components throughout the views. As used in the description herein and throughout the claims that follow, unless the context clearly dictates otherwise, the meaning of “a”, “an”, and “the” includes plural reference, and the meaning of “in” includes “in” and “on”. Titles or subtitles can be used herein for the convenience of a reader, which shall have no influence on the scope of the present disclosure.

The terms used herein generally have their ordinary meanings in the art. In the case of conflict, the present document, including any definitions given herein, will prevail. The same thing can be expressed in more than one way. Alternative language and synonyms can be used for any term(s) discussed herein, and no special significance is to be placed upon whether a term is elaborated or discussed herein. A recital of one or more synonyms does not exclude the use of other synonyms. The use of examples anywhere in this specification including examples of any terms is illustrative only, and in no way limits the scope and meaning of the present disclosure or of any exemplified term. Likewise, the present disclosure is not limited to various embodiments given herein. Numbering terms such as “first”, “second” or “third” can be used to describe various components, signals or the like, which are for distinguishing one component/signal from another one only, and are not intended to, nor should be construed to impose any substantive limitations on the components, signals or the like.

### First Embodiment

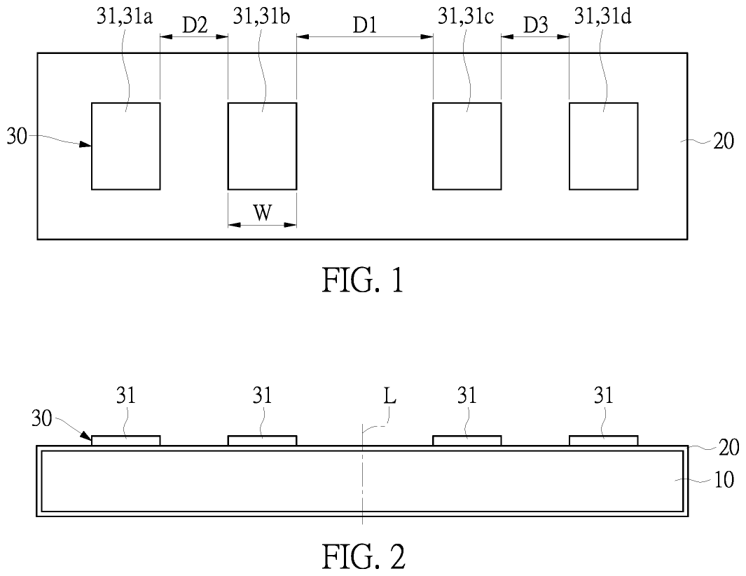

Reference is made to FIGS. 1 and 2, which refer to the first embodiment of the present disclosure. The embodiment of the present disclosure provides a cooling structure having a metal plating layer. The cooling structure having a metal plating layer provided by the embodiment of the present disclosure includes a substrate 10, and a first metal plating layer 20 and a second metal plating layer 30 are made of two different materials and formed on the substrate 10 through a manufacturing process.

In the present embodiment, the substrate 10 can be a copper/copper alloy layer, or an aluminum/aluminum alloy layer. The first metal plating layer 20 may be a plating layer formed on the substrate 10 by a wetting process, and the second metal plating layer 30 may be a metal plating layer having a thickness ranging from 0.1 μm to 5 μm and formed on the first metal plating layer 20 by a sputtering process.

Further, the first metal plating layer 20 may be formed on a surface of the substrate 10 by a wetting process, such as an electroless plating/electroplating process, and the second metal plating layer 30 may be formed on the first metal plating layer 20 through a sputtering process.

In the present embodiment, the first metal plating layer 20 may be formed by electroless nickel plating/electroplating, nickel alloy, or nickel-phosphorus alloy. Therefore, the first metal plating layer 20 may be a nickel/nickel alloy layer, or a nickel-phosphorous alloy layer. Moreover, by forming the first metal plating layer 20 on the surface of the substrate 10, the oxidation resistance and aesthetics of the substrate 10 can be effectively increased.

In the present embodiment, the second metal plating layer 30 may be formed by directly sputtering silver or silver alloy. Therefore, the second metal plating layer 30 can be a sputtered silver/silver alloy layer, so that the second metal plating layer 30 can provide the function of silver sintering, and can be connected with one or more power chips through the function of silver sintering. Moreover, since the second metal plating layer 30 is directly sputtered with silver/silver alloy on the surface of nickel/nickel alloy or nickel-phosphorus alloy, the second metal plating layer 30 is an extremely thin plating layer with high adhesion and good uniformity.

Furthermore, the second metal plating layer 30 includes at least three blocks 31 arranged at intervals, and at least two adjacent ones of the at least three blocks 31 have a distance therebetween that is not equal to a distance between another two adjacent ones of the at least three blocks 31. In the present embodiment, the second metal plating layer 30 includes four blocks 31 arranged at intervals, which can be further divided into blocks 31a, 31b, 31c, and 31d, and an arrangement distance D1 between the block 31b and the block 31c is not equal to an arrangement distance between the other blocks 31. For example, the arrangement distance D1 between the block 31b and the block 31c is not equal to an arrangement distance D2 between the block 31a and the block 31b, or is not equal to an arrangement distance D3 between the block 31d and the block 31c.

This is because if the arrangement distances between the blocks 31 are equidistant, the shrinkage after sintering and the stress impact caused by the change of heat and cold of the power chip during operation are relatively large. Therefore, in the present embodiment, the arrangement distance between at least two blocks 31 is not equal to the arrangement distance between the other blocks 31, so that the blocks on the surface of the nickel/nickel alloy or nickel-phosphorus alloy are arranged at unequal intervals through directly sputtering the silver/silver alloy, thereby reducing stress impact.

In addition, in order to reduce the stress impact more effectively, the blocks 31 are arranged symmetrically with respect to a centerline L of the substrate 10, and the arrangement distance D1 between two blocks 31 closest to the centerline L of the substrate 10 needs to be greater than the arrangement distance between other blocks 31. When each block 31 of the second metal plating layer 30 is rectangular and has a same size (a length, a width, a height), the arrangement distance D1 between two blocks 31 closest to the centerline L of the substrate 10 is twice (1.9˜2.1 times) a width W of each block 31 along the arrangement direction (i.e., along a length direction of the substrate 10). The centerline L mentioned in the present embodiment refers to a straight line that passes through the central point of the substrate 10 and divides the substrate 10 into two symmetrical parts.

### Second Embodiment

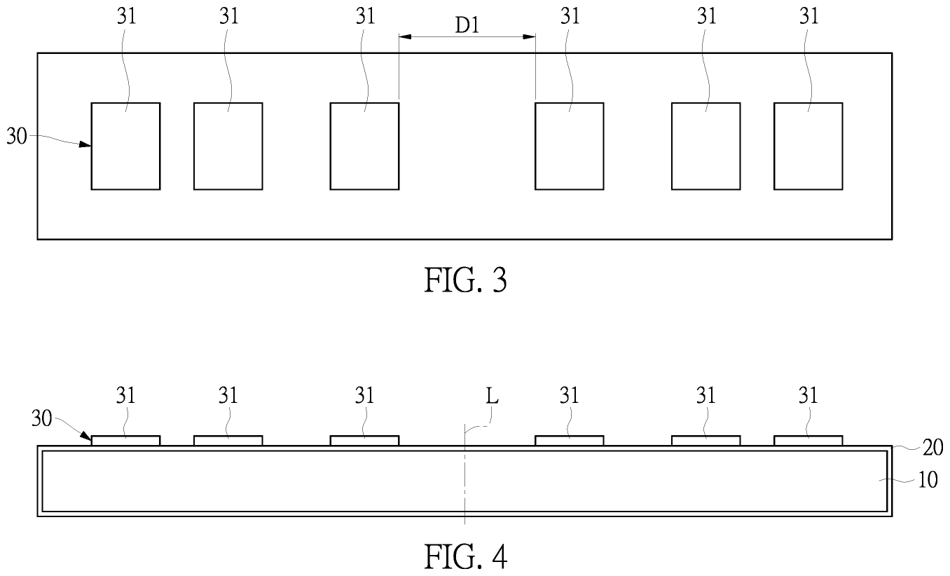

Reference is made to FIGS. 3 and 4, which illustrate the second embodiment of the present disclosure. The present embodiment is substantially the same as the first embodiment, and the differences are described as follows.

In the present embodiment, in the direction away from the centerline L of the substrate 10, the arrangement distance between the blocks 31 gradually decreases. Furthermore, when the arrangement distance D1 between two blocks 31 closest to the centerline L of the substrate 10 is 1 time, the arrangement distance between other blocks 31 is approximately ½ times the arrangement distance D1 (0.45˜0.55 times), ¼ times (0.2025 times˜0.3025 times), ⅛ times (0.091125 times˜0.166375 times), and so on. That is to say, when the arrangement distance between two blocks 31 closest to the centerline L of the substrate 10 is doubled, the arrangement distance between other blocks 31 is gradually decreased by ½\hat{ }N times (0.45\hat{ }N˜0.55\hat{ }N times), in which N starts from 1 and increments by 1. In this way, the variation range of the stress is the smallest (+43.83˜−46.29 MPa) through actual tests. That is to say, the shrinkage of each block 31 of the second metal plating layer 30 after sintering and the stress impact caused by the change of heat and cold of the power chip during operation are minimal, so that the possibility of shrinkage and deformation of the overall cooling structure becomes small, and the plating layer and even the possibility of power die delamination is also reduced.

### Third Embodiment

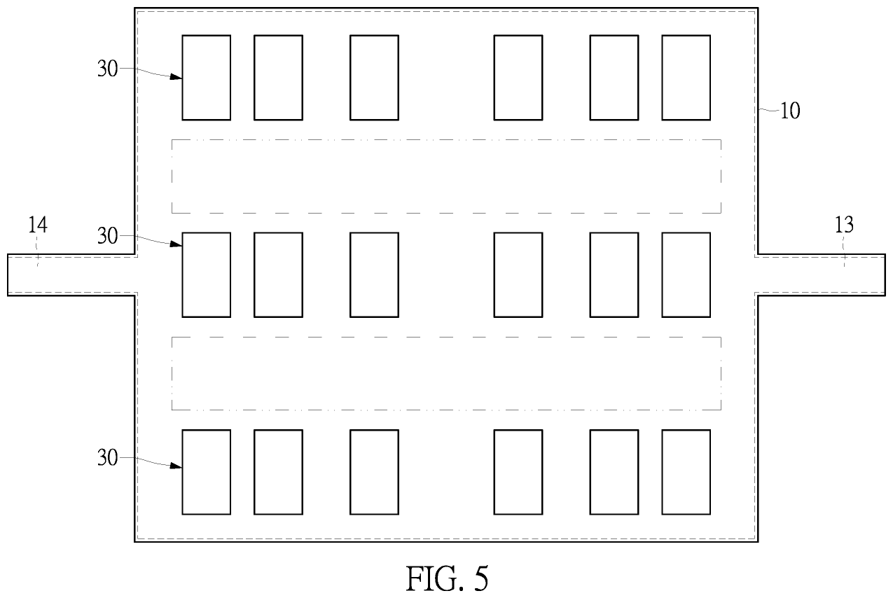

Reference is made to FIG. 5, which illustrates the third embodiment of the present disclosure. The present embodiment is substantially the same as the first embodiment, and the differences are described as follows.

In the present embodiment, the substrate 10 is a closed cooling structure, and has a water inlet 13 and a water outlet 14 that are communicated with each other, so that the cooling fluid can flow into the inside of the substrate 10 through the water inlet 13, flow out from the inside of the substrate 10 through the water outlet 14, and the heat absorbed by the substrate 10 is quickly dissipated.

Furthermore, a plurality of second metal plating layers 30 can be directly formed on the substrate 10 or can be formed on the first metal plating layer on the substrate 10, and the plurality of second metal plating layers 30 are parallel to each other. In the present embodiment, three second metal plating layers 30 are provided, but the number of the second metal plating layers 30 is not limited, and the second metal plating layers 30 can appear repeatedly on the same cooling structure. In addition, each of the second metal plating layers 30 may be configured in the manner shown in the second embodiment, or may be configured in the manner shown in the first embodiment.

### Fourth Embodiment

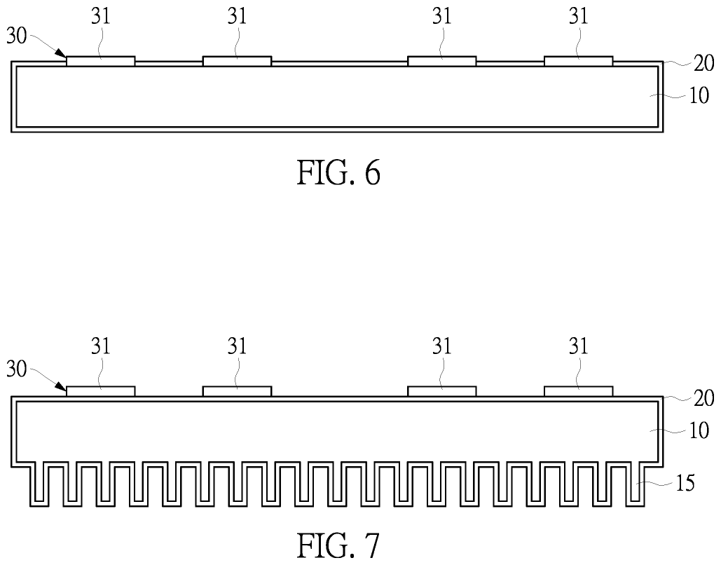

Reference is made to FIG. 6, which illustrates the fourth embodiment of the present disclosure. The present embodiment is substantially the same as the first embodiment, and the differences are described as follows.

In the present embodiment, the second metal plating layer 30 can be directly formed on the substrate 10, and the first metal plating layer 20 can be formed on the substrate 10 not covered by the second metal plating layer 30, or there may not be any first metal plating layer 20 provided. That is, the present embodiment may not include any of the first metal plating layers 20.

### Fifth Embodiment

Reference is made to FIG. 7, which illustrates the fifth embodiment of the present disclosure. The present embodiment is substantially the same as the first embodiment, and the differences are described as follows.

In the present embodiment, in order to increase the heat dissipation area, the substrate 10 may have a plurality of fins 15, and the plurality of fins 15 may be integrally formed on a surface of the substrate 10. Furthermore, the fins 15 of the present embodiment are integrally formed on the surface of the substrate 10 by a machining process, such as cutting or grinding. In addition, the plurality of fins 15 in the present embodiment may be integrally formed on the surface of the substrate 10 by a forging process, and may also be integrally formed on the surface of the substrate 10 by a stamping process. Moreover, in order to have an optimal heat dissipation effect, the plurality of fins 15 in the present embodiment are pin-fins arranged in high density.

In summary, the cooling structure having a metal plating layer provided by the present disclosure can reduce the shrinkage of the second metal plating layer after sintering and the stress impact caused by the change of heat and cold of the power chip during operation by virtue of “a first metal plating layer and a second metal plating layer that are made of materials different from each other and formed on the substrate by different processes,” “the first metal plating layer being formed on the substrate by a wetting process, the second metal plating layer having a thickness ranging from 0.1 μm to 5 μm being formed on the first metal plating layer by a sputtering process,” “the second metal plating layer including at least three blocks arranged at intervals,” and “at least two adjacent ones of the at least three blocks have a distance therebetween that is not equal to a distance between another two adjacent ones of the at least three blocks.”

The foregoing description of the exemplary embodiments of the disclosure has been presented only for the purposes of illustration and description and is not intended to be exhaustive or to limit the disclosure to the precise forms disclosed. Many modifications and variations are possible in light of the above teaching.

The embodiments were chosen and described in order to explain the principles of the disclosure and their practical application so as to enable others skilled in the art to utilize the disclosure and various embodiments and with various modifications as are suited to the particular use contemplated. Alternative embodiments will become apparent to those skilled in the art to which the present disclosure pertains without departing from its spirit and scope.

What is claimed is:

1. A cooling structure having a metal plating layer, including:
a substrate; and
a first metal plating layer and a second metal plating layer that are made of materials different from each other and formed on the substrate by different processes;
wherein the first metal plating layer is formed on the substrate by a wetting process, the second metal plating layer having a thickness ranging from 0.1 μm to 5 μm is formed on the first metal plating layer by a sputtering process, the second metal plating layer includes at least three blocks arranged at intervals, and at least two adjacent ones of the at least three blocks have a distance therebetween that is not equal to a distance between another two adjacent ones of the at least three blocks.

2. The cooling structure having a metal plating layer according to claim 1, wherein the substrate is at least one of a copper/copper alloy layer and an aluminum/aluminum alloy layer.

3. The cooling structure having a metal plating layer according to claim 1, wherein the first metal plating layer is at least one of a nickel/nickel alloy layer and a nickel-phosphorus alloy layer.

4. The cooling structure having a metal plating layer according to claim 3, wherein the second metal plating layer is a silver/silver alloy layer.

5. The cooling structure having a metal plating layer according to claim 1, wherein the plurality of blocks of the second metal plating layer are arranged symmetrically with respect to a centerline of the substrate, and an arrangement distance between two of the blocks closest to the centerline of the substrate is greater than an arrangement distance between the other blocks.

6. The cooling structure having a metal plating layer according to claim 1, wherein, based on the arrangement distance between the two blocks closest to the centerline of the substrate, the arrangement distance between the other blocks is gradually reduced by ½\hat{ }N times of the arrangement distance between the two blocks closest to the centerline of the substrate in a direction away from the centerline, where N starts from 1 and increments by 1.

7. The cooling structure having a metal plating layer according to claim 1, wherein, under a condition that the plurality of blocks are rectangular and have a same size, the arrangement distance between two blocks closest to the centerline of the substrate is twice a width of each block along the arrangement direction.

8. The cooling structure having a metal plating layer according to claim 1, wherein a plurality of fins are integrally formed on a surface of the substrate, and the plurality of fins are pin fins.

9. The cooling structure having a metal plating layer according to claim 1, wherein the substrate has a water inlet and a water outlet that are in fluid communication with each other.

10. The cooling structure having a metal plating layer according to claim 1, wherein multiple ones of the second metal plating layers are formed in parallel with each other on the first metal plating layer on the substrate.

11. A cooling structure having a metal plating layer, including:
a substrate, and a first metal plating layer and a second metal plating layer that are made of materials different from each other and formed on the substrate by different processes;
wherein the first metal plating layer is formed on the substrate by a wetting process, the second metal plating layer having a thickness ranging from 0.1 μm to 5 μm is formed on the first metal plating layer by a sputtering process, the first metal plating layer is formed on the substrate not covered by the second metal plating layer, the second metal plating layer includes at least three blocks arranged at intervals, and at least two adjacent ones of the at least three blocks have a distance therebetween that is not equal to a distance between another two adjacent ones of the at least three blocks.

12. A cooling structure having a metal plating layer, including:
a substrate, and at least a metal plating layer formed on the substrate, wherein the metal plating layer having a thickness ranging from 0.1 μm to 5 μm is formed on the substrate by a sputtering process, the metal plating layer includes at least three blocks arranged at intervals, and at least two adjacent ones of the at least three blocks have a distance therebetween that is not equal to a distance between another two adjacent ones of the at least three blocks.
